(19) United States
(12) Patent Application Publication
(10) Pub. No.: US 2013/0204555 A1
(43) Pub. Date: Aug. 8, 2013

(54) Method and Apparatus for Electrically Locating a Fault in a Cable

(71) Applicants: Sven SCHEUSCHNER, Radeburg (DE); Matthias HIRTE, Magdeburg (DE); Joerg PETZOLD, Magdeburg (DE); Thomas GEBHARDT, Ottendorf-Okrilla OT Medingen (DE)

(72) Inventors: Sven SCHEUSCHNER, Radeburg (DE); Matthias HIRTE, Magdeburg (DE); Joerg PETZOLD, Magdeburg (DE); Thomas GEBHARDT, Ottendorf-Okrilla OT Medingen (DE)

(21) Appl. No.: 13/760,384

(22) Filed: Feb. 6, 2013

(30) Foreign Application Priority Data
Feb. 6, 2012 (DE) 10 2012 002 439.8
Mar. 28, 2012 (DE) 10 2012 006 332.6

(51) Int. Cl. G01R 31/08; G01R 23/16

(52) U.S. Cl. CPC G01R 31/088; G01R 23/16
USPC 702/59; 324/520

(57) ABSTRACT

In order to locate a cable fault in a cable, a testing apparatus applies a test signal to the cable so as to induce an electrical oscillation. The testing apparatus includes a voltage source that generates the test signal, which e.g. ignites an electrical arc at the cable fault or applies a voltage surge to the cable, to cause the electrical oscillation. The apparatus further includes a measured signal evaluation device to measure the resulting oscillations in the time domain or the frequency domain, and carry out a spectral analysis in the frequency domain, so as to automatically determine the location of the fault preferably from the total phase rotation of the signal, the phase rotation of the reflection at the first cable end, the phase rotation of the reflection at the cable fault, and the imaginary part of the propagation constant of the signal in the cable.

### PRIORITY CLAIM

This application is based on and claims the priority under 35 USC 119 of German Patent Applications DE 10 2012 002 439.8 filed on Feb. 6, 2012, and DE 10 2012 006 332.6 filed on Mar. 28, 2012, the entire disclosures of which are incorporated herein by reference.

### FIELD OF THE INVENTION

The invention relates to a method and an apparatus for electrically testing a cable with a testing apparatus for locating a cable fault in the cable under test. The testing apparatus and the test cable together form an electrical system.

### BACKGROUND INFORMATION

The electrical testing of cable systems of large expanse or of high complexity for locating cable faults in these cable systems is well known in the prior art, and is the subject matter of many patent applications. For example, see the German Patent Applications DE 22 010 24 A, DE 196 172 43 A1, DE 100 194 30 A1, and DE 24 550 07 A1. The established methods of locating a cable fault in a cable system typically use the time difference between an emitted time signal such as an electrical pulse applied to the cable, and a received time signal resulting when the emitted signal is reflected back along the cable from the cable fault. Based on a known pulse propagation speed in the cable, as well as the measured time difference, it is thus possible to calculate the distance traveled by the pulse along the cable until reaching the fault location and reflecting back from it.

In order to accurately determine the fault location, it is necessary to measure the reflected signals that are coupled out of the cable with only a rather small amplitude. Thus, this measurement is made more difficult by interference signals that are present, for example interference signals that have been coupled into the cable from the surrounding environment. Such interference signals tend to mask or falsify the small-amplitude reflection signals of interest. Furthermore, the evaluation of the measured data is also made more difficult because multiple reflections typically arise in the cable, due to a multiplicity of reflection points, e.g. points of variation of the characteristic wave impedance in the cable being tested. It is desired to reduce or avoid the above problems in a method and apparatus for locating a fault in a cable.

### SUMMARY OF THE INVENTION

In view of the above, it is an object of the invention to provide a method and an apparatus for electrically testing a cable so as to locate a fault in the cable, while avoiding or improving on disadvantages or shortcomings of the prior art. For example, the invention aims to avoid or minimize the negative influences of interference signals, multiple reflections and low-amplitude useful signals. More particularly, the invention aims to avoid the use of a signal transit time for calculating the location of the cable fault. Still further, the invention especially aims to excite an electrical oscillation in the cable, determine certain electrical parameters of the signal in the cable, and from these parameters determine an electrical or geometric length of the cable from the tested end to the cable fault location. The invention further aims to avoid or overcome the disadvantages of the prior art and to achieve additional advantages as apparent from the present specification. The attainment of these objects is, however, not a required limitation of the claimed invention.

The above objects have been achieved according to the invention in a method of locating a cable fault in a cable under test using a testing apparatus. Thereby, an electrical system is formed that comprises the test cable together with the testing apparatus. An embodiment of the inventive method may include the following steps:

determining a first phase rotation or phase shift occurring at a first end of the test cable, a second phase rotation or phase shift occurring at a second end (e.g. the fault location) of the test cable, and a propagation constant for an electrical signal in the test cable;

exciting an electrical oscillation in the test cable or in the entire electrical system;

measuring the electrical oscillation and thereby determining a frequency spectrum or a time signal of the electrical oscillation;

if a time signal of the electrical oscillation was determined, then optionally transforming the time signal into a frequency domain to determine a frequency spectrum;

performing a frequency analysis of the frequency spectrum;

from the frequency analysis, determining a total phase rotation or phase shift of the forward and return signal; and

from one or more of the abovementioned parameters, determining an electrical length or a geometric length of the test cable from the first cable end to the cable fault at the second cable end. From this, the location of the cable fault along the cable may be determined.

The above objects have further been achieved according to the invention in an apparatus comprising respective means or components for performing the steps of the inventive method.

The inventive method makes it possible to locate a cable fault in a cable by using the resonance characteristics of the cable, and particularly the portion of cable between the cable fault and the first cable end at which the testing apparatus is connected.

Furthermore, maxima of the oscillation and their order can be determined, from which it is possible to automatically determine the electrical length of the test cable or particularly the test cable portion between the first cable end and the cable fault.

Before further details of the terminology, methodology and apparatus used according to the present invention are explained, first the mathematical principles underlying the location of cable faults will be explained. Thereby, an understanding of the invention will be supported and facilitated.

A test cable, i.e. an electrical conductor cable that is to be tested for determining the presence and location of a cable fault therein, such as a power cable for example, can be understood as an electrical resonator or resonating element of an electrical system. Beginning from Kirchhoff's current law and Kirchhoff's voltage law, the conductor theory provides a system of coupled differential equations that describe the dynamic behavior of the currents and the voltages in a conductor:

$$\begin{matrix}- \frac{\partial u ( z , t )}{\partial z} = {R}^{′} \cdot i ( z , t ) + {L}^{′} \cdot \frac{\partial i ( z , t )}{\partial t} & Eq . ( 1 ) \\ - \frac{\partial i ( z , t )}{\partial z} = {G}^{′} \cdot u ( z , t ) + {C}^{′} \cdot \frac{\partial u ( z , t )}{\partial t} & Eq . ( 2 )\end{matrix}$$

The values L′, C′, R′ and G′ indicate the values of the well-known pertinent electrical characteristics of the conductor per unit length, and can be visualized in an equivalent circuit diagram representing the conductor (for example see FIG. 1).

Expressed differently, the above conductor equations (1) and (2) describe the electrical response by the system or the system component formed by the conductor, to an external electrical excitation. In that regard, the particular type, e.g. the particular characteristic features, of the electrical excitation, namely the form of the current or voltage signal that is applied to the conductor, has a decisive influence on the electrical response that will arise. If the system is harmonically excited with an applied signal at a frequency that corresponds to or is close to the resonance frequency of the system, then this will result in a current and/or voltage response having a maximum amplitude. On the other hand, if an applied test signal has a frequency farther away from the resonant frequency, then a smaller amplitude response will arise. If the resonance frequency of the conductor, e.g. the cable, or the entire system is unknown, then a broadband excitation by a signal covering or including a range of frequencies will give rise to a response signal in which the individual harmonic components of the excitation and their reflections at the ends of the conductor will be superimposed on one another. Such a broadband excitation can, for example, be given by a sharp voltage dip or a current pulse with short rise times, for example as arise when igniting an electrical arc. If the superimposed waves that are traveling in the same direction have a phase offset of a multiple of 360° relative to one another, then these waves will be constructively superimposed and give rise to the formation of standing waves of greater amplitude. Such waves are not affected by the missing phase offset of the effects of a destructive superposition or interference, and thus propagate over a longer time duration. Based on this phenomenon, in an unknown conductor system, for example including an unknown test cable, the electrical length of the conductor, e.g. the cable, can be determined by measuring the frequencies at which standing waves propagate in the conductor.

The following relationship arises from the condition for the constructive superposition of the waves:

$$L = n \cdot \frac{λ}{2} = n \cdot \frac{c}{2 f} \qquad Eq . ( 3 )$$

The conductor equations set forth above are differential equations that can be solved in view of the statement of plane waves:

$$u ( z , t ) = \underbrace{{u}_{1} \cdot {e}^{j ω t - γ z}}_{forward traveling wave} + \underbrace{{u}_{2} \cdot {e}^{j ω t + γ z}}_{return traveling wave} \qquad Eq . ( 4 )$$

as well as

$$i ( z , t ) = \underbrace{\frac{{u}_{1}}{{Z}_{0}} \cdot {e}^{jω t - γ z}}_{forward travelin g wave} - \underbrace{\frac{{u}_{2}}{{Z}_{0}} \cdot {e}^{jω t + γ z}}_{return traveling wave} \qquad Eq . ( 5 )$$

wherein Z₀ is the characteristic wave impedance of the conductor

$${Z}_{0} = \sqrt{\frac{{R}^{′} + jω {L}^{′}}{{G}^{′} + jω {C}^{′}}} \qquad Eq . ( 6 )$$

and γ is the complex propagation constant:

γ=\sqrt{(R′+jωL′)·(G′+jωC′)} Eq. (7)

The propagation constant γ is complex and includes a phase component β, which identifies the phase rotation of an infinitesimally small conductor element.

The above described equations apply only to loss-free ideal conductors. On the other hand, for lossy conductors, the frequency dependence of γ and β becomes significantly more complicated due to an additional frequency dependence of all characteristic parameters of the conductor. Thus, a dispersion of the signal arises.

The phase component β plays a decisive role in the determination of the distance to the fault from the first free end of the cable. This phase component β can be most easily determined according to the following equation (8) by measuring the frequency dependent phase velocity of the signals on the conductor:

$$β = \frac{2 π f}{c} \qquad Eq . ( 8 )$$

The resulting solution has two unknowns in the variables u1 and u2, so that there would be an infinite number of solutions. In order to be able to solve the conductor equations unambiguously, it is necessary to specify boundary conditions at which the relationship between the currents and the voltages is known. Starting from these boundary conditions, with the aid of the conductor equations, the current and voltage progression over the entire conductor can be calculated. At the location of the respective known boundary condition, both the boundary condition itself as well as the conductor equation must validly apply. For a terminal impedance ZL at the location z=0, thus there arises:

$${Z}_{L} = \frac{U ( z = 0 )}{I ( z = 0 )} = \frac{{u}_{1} \cdot {e}^{j ω t} + {u}_{2} \cdot {e}^{j ω t}}{\frac{{u}_{1}}{{Z}_{0}} \cdot {e}^{jω t} - \frac{{u}_{2}}{{Z}_{0}} \cdot {e}^{j ω t}} \qquad Eq . ( 9 )$$

By transposing, this gives the reflection factor r:

$$r = \frac{{u}_{2}}{{u}_{1}} = \frac{{Z}_{L} - {Z}_{0}}{{Z}_{L} + {Z}_{0}} \qquad Eq . ( 10 )$$

With this reflection factor r, the conductor equations can be solved. Furthermore, this reflection factor r can be directly measured through the use of a network analyzer.

Because the ends of the test cable, e.g. a power cable under test, are each terminated with a respective known impedance, they can be used as respective boundary conditions. Namely, one end of the pertinent cable section is the location of the cable fault at which the ignited electrical arc represents a short circuit, while the other end is the free first cable end connected to and terminated by the testing apparatus having a known input impedance.

In view of the above mathematical explanation, the distance from the first cable end to the cable fault location can be calculated as follows. From the solutions of the above cable equations, the phase relationships of all waves propagating along the conductor can be established. The total phase rotation or total phase shift of a wave that travels forward along the cable to the fault location and then returns back along the cable is given by

$$φ = \underbrace{β l}_{forward traveling wave} + \underbrace{arg ( {r}_{2} )}_{reflection at end} + \underbrace{β l}_{return traveling wave} + \underbrace{arg ( {r}_{1} )}_{reflection at end} \qquad Eq . ( 11 )$$

Reconfiguring this equation, the cable length/is given by

$$l = \frac{ϕ - arg ( {r}_{2} ) - arg ( {r}_{1} )}{2 β} \qquad Eq . ( 12 )$$

Thus, in order to be able to determine the geometric length, i.e. the cable length and/or the distance to the cable fault location, the following frequency dependent parameters must be known:

arg(r1)=phase rotation or phase shift of the reflection at the first end of the conductor;

arg(r2)=phase rotation or phase shift of the reflection at the second end of the conductor (at cable fault);

φ=total phase rotation or phase shift; and

β=imaginary part of the propagation constant γ.

The determination of these parameters will be demonstrated below in connection with a particular example embodiment.

In view of and on the basis of the above described theory, the following conceptual and definitional aspects of the invention will be further explained.

The term “cable fault” herein encompasses all faults of the cable that would lead to unacceptable performance, such as unacceptable electrical parameters, e.g. continuity, resistance, impedance, security of the insulation, etc. The term “cable fault” especially preferably encompasses all insulation faults of the insulation of the cable, which are permanent/irreversible, or intermittent, or reversible, with respect to a voltage applied to the cable, and especially a very low frequency (VLF) voltage. For example, a cable fault is present when an insulation breakdown has occurred. A reversible cable fault is present especially if an insulation breakdown has occurred, but a repair mechanism or a treatment has successfully “healed” the fault location in the cable insulation. This can occur, for example, in an oil-insulated cable, because during a breakdown the electrical discharge through the insulation at the fault location leads to liquidization of the oil insulation, which then may flow into a dried-out critical area of the insulation and thereby again increase the insulation strength in this area. Thereby the fault is said to have been “healed” if the fault location in the insulation has again been brought up to an acceptable insulation performance level.

The term “locating” a cable fault is understood to mean, among other things, fixing the position of a cable fault in the test cable, or at least limiting the local range at which the cable fault is located in the test cable. For example, this can be understood as a precise or fine locating, or a coarse or general locating of the cable fault. The term “locating” also encompasses simply determining the electrical length or the geometric length and further values derived therefrom, with regard to the cable section from a first cable end thereof to the cable fault location. For example, the position and thus the location of the cable fault especially corresponds to the electrical length of the test cable from the measuring location (e.g. the first cable end at which the test apparatus is connected), alternatively the position is the “location” φ/β (see above equation 12). The geometrical length l can especially be determined from the electrical length minus (phase rotation at the cable ends)/2β. Thus, if the path of a buried or otherwise enclosed cable or of an open accessible cable is known, then the location of the cable fault can be exactly determined or at least localized within a limited range based on the determined geometrical length traced back along the cable from the test end thereof.

The term “test cable” encompasses the cable that is to be tested. Such a cable is especially, for example, a middle voltage cable for a VLF voltage, or a high voltage cable, or a low voltage cable. Furthermore, the term test cable includes all cables having an insulation, including both open exposed cables as well as buried cables and cables laid in conduits, chases, or the like.

A “testing apparatus” herein is any apparatus or device that can be electrically coupled to the test cable and used for measuring electrical characteristics of the cable. Particularly, the testing apparatus can measure the time and/or frequency signals of electrical oscillations and electrical waves in the test cable, phase rotations or phase shifts of the reflections at the ends of the test cable, the total phase rotation, the imaginary part β of the propagation constant γ and/or the wave impedance of the cable conductor. Furthermore, the testing apparatus is able to apply an electrical test signal to the cable so as to induce an electrical oscillation and especially a resonance in the cable or in the overall electrical system including the cable the testing apparatus. For example, this can be achieved by a pulse generator or a surge generator included in the testing apparatus. In this regard, such a surge generator can generate narrowband or broadband burst signals and apply or impose these burst signals on the test cable. Moreover, the testing apparatus can initiate the ignition of an electrical arc at a cable fault in the test cable. Any known electrical test equipment, or electrical components, for carrying out the necessary functions and method steps disclosed herein can be combined, connected and used as needed according to the inventive method. The testing apparatus may, but does not have to be, a self-contained single unit including all of the necessary components for carrying out all aspects of the inventive method. Alternatively, the testing apparatus may include plural separate devices that are connected or used together to carry out the inventive method.

The “electrical system” herein comprises both the test cable as well as the testing apparatus or the overall measuring system electrically coupled thereto. This electrical system can especially also be simulated and modeled as such. Thereby individual parameters can be determined.

The term “first phase rotation” and “second phase rotation” refer to the phase shifts that occur in the signal at the ends of the pertinent section of the cable, and encompass the parameters of the mathematical representations arg(r1) and arg(r2), as they are used in the above equations (11) and (12).

The term “first cable end” and the term “second cable end” refer to the open end of the test cable or the location at which the testing apparatus is electrically coupled to the test cable, and the location of the cable fault in the test cable, or vice versa.

The term “propagation constant” means the parameter of the mathematical representation γ, or at least the imaginary part β thereof, as used in the equations (7), (8), (11) and (12) set forth above.

An “electrical oscillation” in the test cable or in the electrical system encompasses both individual electrical oscillations in the test cable or in the electrical system as well as waves, e.g. standing waves, that arise. The electrical oscillation can especially be produced by initiating the ignition of an electrical arc at a fault location or by imposing a (broadband) signal onto the electrical system or the test cable.

The phrase “measuring the electrical signal” especially preferably means measuring a time signal of the current, the voltage, the electric field or the magnetic field of the electrical oscillation. This phrase also preferably encompasses a measuring process in the frequency domain, or a measurement carried out with a spectrum analyzer, in which the time signal has already been transformed into a frequency signal.

The “frequency analysis” especially preferably involves separating superimposed time signals having different oscillation periods and rise times. In that regard, for example, a Fast Fourier Transformation (FFT) or an electronic filter can be utilized, which limits the bandwidth of the measuring system to the spectral components of the useful signal. Through the use of the FFT or the filter, this gives rise to the “frequency spectrum”, which generally encompasses all representations of the frequencies of the time signal.

The term “total phase rotation” refers to the total phase shift experienced or exhibited by the forward and return signal, for example as indicated by the parameter of the mathematical representations φ, as used in the above equations (11) and (12).

An “electrical length” refers to the parameter of the mathematical representations l, as used in the above equations (11) and (12). In practical terms, this can correspond to the length or distance along the cable from one test cable end (at which the testing apparatus is connected) to the location of the cable fault. Furthermore, the explanations given as to the term “locating” are also pertinent with regard to the “electrical length”.

In order to be able to inform the user of the inventive method and apparatus regarding the location of the cable fault, without requiring the user to have extensive experience or knowledge in this field, and without requiring additional effort by the user, the frequency analysis may further include an automatic detection of relevant signal maxima. A simple determination of the (local) maxima can be carried out, for example, by comparing a local signal value with the respective neighboring data points to the right and to the left of the signal value of interest. However, in a further preferred particular embodiment, the automatic detection of a relevant maximum can be carried out in connection with an interval width and/or a threshold value for evaluating the signal value. Thereby, so-called “parasitic” maxima and unresolved maxima can be recognized and cleaned-up, i.e. filtered out or excluded from the useful signal data. The “parasitic maxima” can especially arise due to broadband noise and/or superimposed interference signals, which are formed, for example by arising inhomogeneities of the cable impedance.

In order to exclude interference effects and parasitic maxima, and to improve the signal quality of the frequency spectrum, the automatic detection in a particular embodiment may especially comprise applying a filter with variable boundary frequency on the frequency spectrum. Thereby, that can further comprise a frequency transformation of the frequency spectrum with subsequent multiplication by a variable window function, and final transformation back into a “cleaned” or filtered frequency spectrum. Then the relevant maxima are determined in this cleaned or filtered frequency spectrum.

Furthermore, in a particular embodiment of the invention, in the use of the filter with variable boundary frequency, a relevant maximum or several relevant maxima can be shifted. Thereby the resolving of the maxima can be improved.

In order to enable and/or to improve the modeling or simulating of the location of the cable fault, the inventive method further may involve determining the orders of the relevant maxima of the frequency spectrum or of the cleaned or filtered frequency spectrum. The orders of the maxima of the time signal may also be determined.

In a further embodiment of the inventive method, a respective reliability value can be allocated respectively to each relevant maximum. Through a variable or differentiated selection of maxima based on the reliability values, it is possible to obtain different simulation or modeling results.

In order to improve the result of the determination of the cable length and thus therewith the determination of the location of the cable fault, an electrical oscillation behavior, especially a breakdown voltage and the electrical length of the test cable, can be modeled respectively differently for different reliability levels in view of the abovementioned reliability values. For so example, a “reliability level” can correspond to a boundary or threshold value, below which a particular maximum is characterized as not relevant. In other words, if the reliability value allocated to a particular maximum falls below the specified reliability level or threshold, then this maximum is ignored or not used in the evaluation.

The “modeling” similarly encompasses an electronic or computer modeling or simulating of the electrical system or of the test cable. For example, the known “SPICE” (Simulation Program with Integrated Circuits Emphasis) program for simulation of electronic circuits, or the Matlab/Simulink program can be used as a computer modeling tool.

According to an additional embodiment, the measurement of the imposed or induced oscillation can be carried out in the time domain, and then transformed into the frequency domain by a suitable transformation. Thereby, finally, the locating of the cable fault can be improved or even made possible in the first place.

As mentioned above, a further aspect of the invention provides an apparatus suitably embodied for carrying out the disclosed method. Thereby, an apparatus is provided for use on site for testing the cable and analyzing any cable fault in the cable.

### BRIEF DESCRIPTION OF THE DRAWINGS

In order that the invention may be clearly understood, it will now be explained in further detail with reference to the accompanying drawings, wherein:

FIG. 1 is a schematic illustration of a representative equivalent circuit diagram representing a conductor with the associated idealized components and mathematical relationships;

FIG. 2 is a schematic flow diagram of an example of a method according to the invention;

FIG. 3 is a schematic block diagram of major components of an example of a testing apparatus according to the invention;

FIG. 4 is a graph of a frequency spectrum showing the amplitude as a function of frequency of a measured signal, along with respective confidence values assigned to peaks of the spectrum; and

FIG. 5 is a graph showing the spectrum of FIG. 4, as well as a processed signal representing the weighted relative frequency of occurrence of signal peaks.

### DETAILED DESCRIPTION OF PREFERRED EXAMPLE EMBODIMENTS AND THE BEST MODE OF THE INVENTION

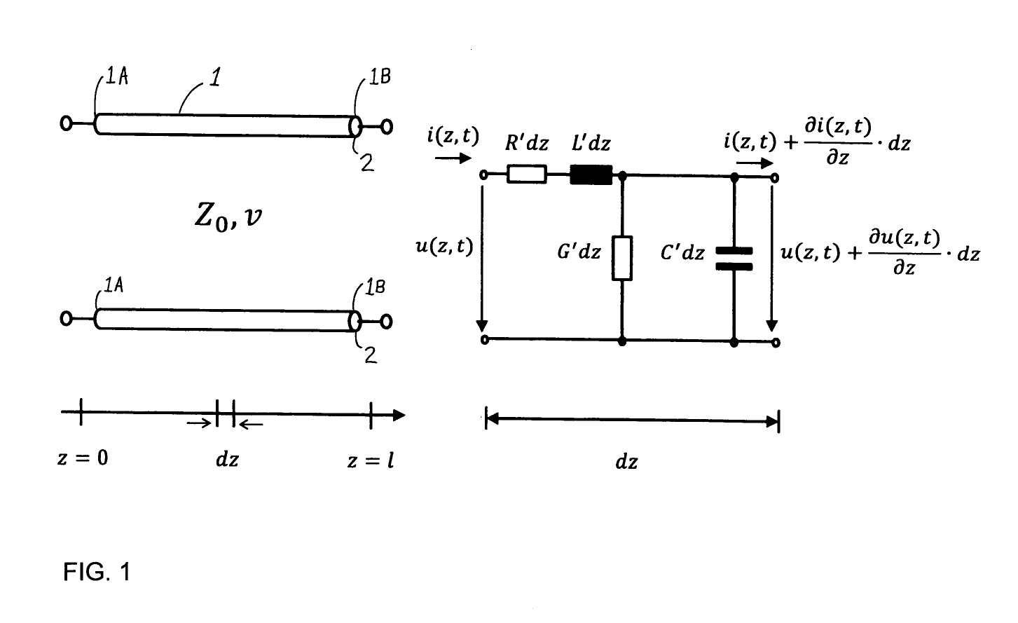

In the schematic diagram of FIG. 1, a test cable 1, i.e. a cable that is to be tested for locating a cable fault 2 therein, is represented physically extending from the physical location or length z=0 at a first cable end 1A of the test cable 1, to the physical location or length z=l at a second cable end 1B of the test cable 1. This second cable end 1B is not a second free end of the total length of the cable, but rather corresponds to a cable fault location of the cable fault 2, because at this cable fault 2 the cable is effectively electrically terminated by a short circuit due to breakdown of the cable insulation by an electrical arc that is ignited during the testing. The purpose of the testing is ultimately to determine the physical length of the cable 1 from the first cable end 1A to the second cable end 1B, i.e. the location of the cable fault 2 along the length of the cable. With that information, it is a simple matter to trace back along the cable from the first cable end 1A to the determined length, which then gives the location of the cable fault 2.

Also shown in FIG. 1 is a schematic representation of an infinitesimally small length portion dz of the test cable 1, as well as the electrical representation of the electrical parameters of such an infinitesimally small portion of the test cable 1 in the equivalent circuit shown at the right side of FIG. 1. These electrical parameters are used in and related to the equations that have been generally discussed above, for example see equations (1), (2), (6), (7).

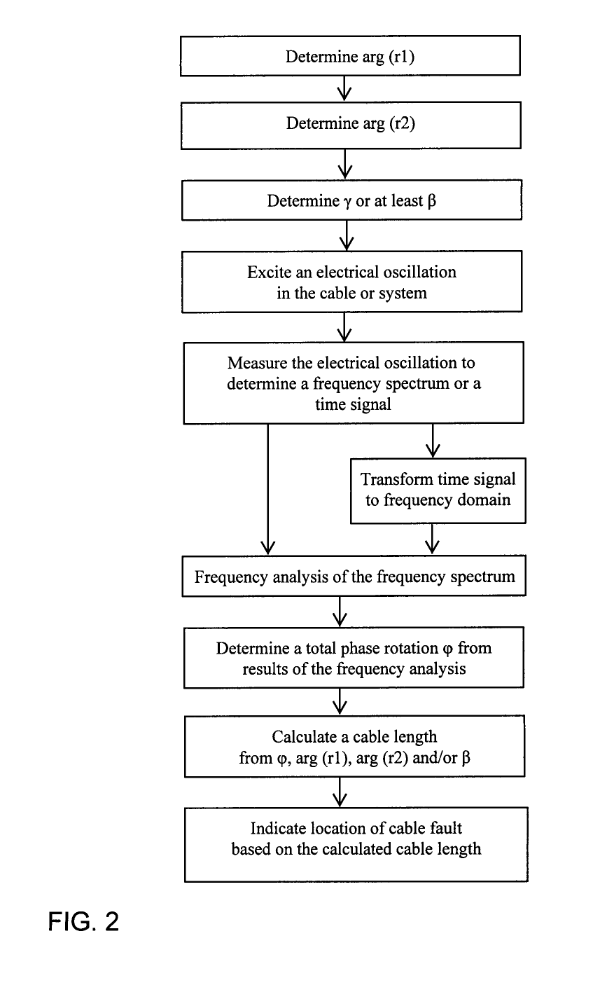

FIG. 2 is a schematic flow diagram showing representative steps of an example embodiment of the inventive testing method for determining the location of the cable fault 2 in the test cable 1. For example, FIG. 2 represents steps of the inventive method that has been generally discussed above, and will be discussed with further details in connection with a particular embodiment below. It is not necessary that all of the indicated steps in FIG. 2 must be performed in the exemplary sequence shown in FIG. 2. For example, the sequential order of determining arg(r1), arg(r2) and γ or β is not limited to the sequence shown in FIG. 2, but rather can be performed in any other sequence or simultaneously. Similar considerations apply to the order or sequence of other steps.

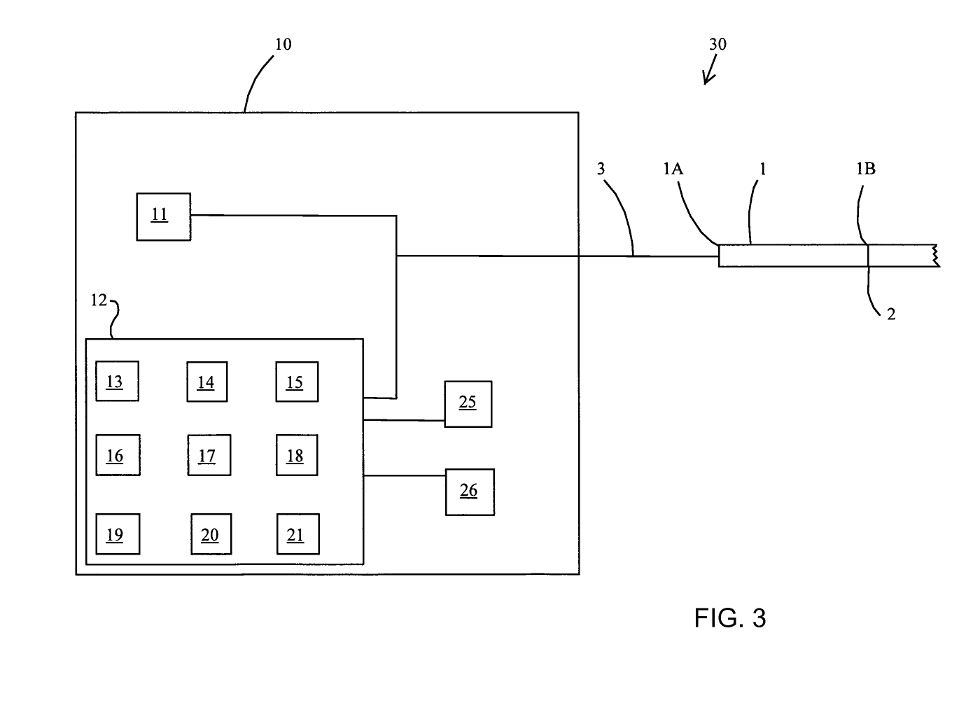

FIG. 3 is a block diagram representing a testing apparatus 10 according to the invention, connected by a testing lead 3 to the first cable end 1A of the test cable 1, which has a cable fault 2 at a fault location represented as an electrically effective second cable end 1B during the testing. Thereby, the testing apparatus 10, the testing lead 3, and the cable 1 from the first cable end 1A to the second cable end 1B form an electrical system 30 during the testing. The testing is carried out according to an inventive method as generally discussed above, and as will be discussed in connection with further details of an example embodiment below. The testing apparatus 10 in this example embodiment comprises a high voltage source 11, such as e.g. a pulse signal source, a variable frequency source and/or a voltage surge generator, for applying selected voltage signals to the test cable 1 and inducing electrical oscillations therein. The testing apparatus 10 further comprises a measured signal evaluation device 12 for measuring and evaluating resultant signals that arise on the test cable 1 from application of the test signal to the test cable 1 by the voltage source 11. The testing apparatus still further includes a user input device 25 such as e.g. a touch screen, a keyboard, a pointing and selecting device such as a mouse or the like, or an electrical connector for connection to an external memory or other input device. The testing apparatus 10 also includes an output device 26, such as e.g. a computer display screen, a printer, or a data output connector. For carrying out the signal measurement and evaluation according to the inventive method, the measured signal evaluation device 12 may include any one or more of the following components: a frequency-dependent impedance measuring device 13, a frequency-dependent phase measuring device 14, a signal timer device 15, a Fast Fourier Transform (FFT) circuit or device 16, an electronic filter or filter arrangement 17, a frequency or spectrum analyzer 18, a comparator 19, a computer processor 20 that may have loaded therein and may execute any or all necessary algorithms, method step sequences and/or programs for carrying out various embodiments of the inventive method as disclosed herein, and a memory 21 in which user-defined threshold values, interval values, successive measured signal values, programs, parameters, and the like may be stored.

In order to determine the electrical length of the relevant section of the test cable from the first cable end 1A to the second cable end 1B, i.e. the location of the cable fault 2, and for determining further parameters according to the inventive method as discussed herein, certain basic parameters must be measured, calculated or otherwise determined, as follows.

The reflection factors are values that are independent of the particular test cable 1 being tested, and as such, the reflection factors were separately previously determined. The reflection factor values can then be stored, for example, in the memory 21 of the measured signal evaluation device 12 of the testing apparatus 10.

As described above, to carry out the testing, the testing apparatus 10 is connected to the first cable end 1A of the cable 1 by the lead 3. Thereby, the first cable end 1A is terminated and coupled with the known impedance of the testing apparatus 10, and the apparatus 10 serves to generate the high voltage test signals and apply them to the cable 1, and also to couple the measured signals out of the cable 1 and evaluate these measured signals.

The phase rotation arg(r1) of the signals at the first cable end 1A of the test cable 1 and the impedance are measured once in a frequency-dependent manner, e.g. by test signals that scan over a suitable frequency range or include a broadband range of frequencies, and then the determined values of these parameters are stored, for example in the memory 21 of the apparatus 10.

The phase rotation arg(r2) of the signals at the second cable end 1B of the test cable 1 is assumed as known, because the cable fault 2 at the second cable end 1B represents a short circuit during the testing. As such, the resultant known phase rotation of the short circuit, e.g. a voltage phase shift of 180°, is specified for example via the user input 25 and/or can be stored in the memory 21.

The propagation constant γ is dependent on the dimensions, the geometry and the material of the test cable 1. The propagation constant γ is always approximately the same for all cables of a certain type, and varies only slightly due to production tolerances among cables of a given type. Thus, the propagation constant can be specified in advance, for example via the user input 25 and/or stored in the memory 21. The imaginary part β of the propagation constant γ of a specific test cable 1 can thus either be determined/measured for the actual cable by measuring the frequency dependent phase velocity of the test signal in this particular test cable 1, or it can be looked-up from the cable specifications provided on the data sheet for this cable (usually not frequency dependent). Alternatively, it can be directly measured by the measured signal evaluation device 12.

The total phase rotation φ is given by or arises from the resonance condition (see above equation (3)), i.e. from the resonance frequencies and their order, which are automatically determined as explained in the following. The resonance is established in the test cable 1 or in the overall electrical system 30 by the electrical excitation of the system by a test signal applied by the voltage source 11 of the testing apparatus 10, whereby standing waves are induced between the first cable end 1A and the cable fault 2 at the second cable end 1B of the test cable 1.

The following discussion will explain the frequency analysis, i.e. the automatic detection of the resonance frequencies and their orders, as conducted according to an example embodiment of the inventive method.

Generally, measurements serve for obtaining information. However, the informations contained within a time signal may not always be easily detected, acquired and read-out. Rather, noise and interference signals are often superimposed on the useful signal and thus make an evaluation of the useful signal more difficult and less accurate. In this regard, it can already be helpful to utilize and evaluate different forms of representation of the same data set in order to avoid or minimize the problematic influences of noise, interference signals, and the like.

Thus, for example, various signals that are superimposed on one another and that have different oscillation periods and different rise times are separated from one another by carrying out a Fast Fourier Transformation (FFT) on the resulting superimposed composite signal. Alternatively, an electronic filter is used to separate noise and interference from the useful signal, in that the filter limits the bandwidth of the measuring system to the spectral range of the desired portions of the useful signal. In the case that the spectral portions of the useful signal and of the interference signal lie too close to one another in order to be able to separate them from one another in the frequency domain, and/or if the spectral portions of the useful signal are unknown at the outset, or in some circumstances these spectral portions of the useful signal are the measured values to be determined by the testing, then a further resolving of the maxima of the measured signal is to be carried out as described in the following.

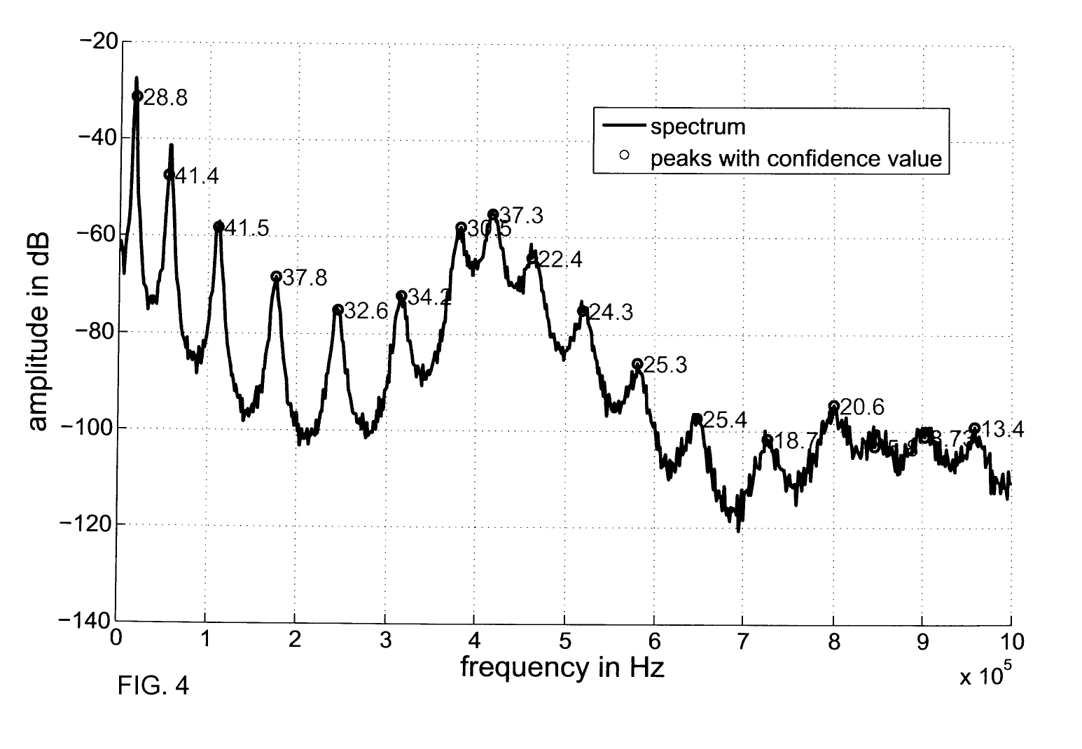

For solving the above equations for determining the distance to the cable fault 2 from the first cable end 1A, it is preferred according to the invention to perform an analysis of the frequency spectrum of the time signal that is acquired or recorded during the testing of the test cable 1 having the cable fault 2 (for example, see FIG. 4). The object of this frequency spectrum analysis is the reliable and automatic detection of the relevant maxima in the spectral progression. In that regard, it is significant to determine not only the individual maximum, but rather also the order thereof. If a relevant maximum is not recognized when progressing from lower frequencies to higher frequencies in the frequency spectrum analysis, then an incorrect order will be assigned or allocated to the following peaks at higher frequencies. This would have an effect on the final calculation of the distance to the cable fault.

In that regard, two basic problems must be addressed and resolved. First of all, the measured time signal is subject to various diverse interferences, for example such as a broadband noise or various particular interference signals superimposed on the useful signal in the measured time signal. Such interference signals may arise due to existing inhomogeneities of the cable impedance. This similarly has an effect on the spectrum, so that the data are not present as a smooth signal progression, but rather parasitic maxima arise in the spectrum. Due to these fluctuations, it is not possible to use simple algorithms on the raw data for determining the maxima. For example, the simplest way conceivable for finding a local maximum is to compare a respective data point with the neighboring data points lying to the right and to the left of the subject data point, to determine whether the subject data point has a greater value than its neighbors. Such a simple determination of a local maximum would, however, determine many additional false maxima.

Such a simplistic method can be improved or expanded through the use of additional parameters. For example, a frequency interval width can be specified in which a maxima will be locally searched for; in other words the “locality” of the local maximum is expanded. Alternatively, a limit value or threshold can be introduced, which specifies at what level or magnitude difference a particular maximum will be accepted as such, so as to omit data points that have a magnitude only slightly greater than neighboring data points. For this reason values, for example for the interval width and/or the peak height, are selected. However, in this regard there is the basic underlying problem, that the most advantageous value for such thresholds or parameters is dependent on system dimensions or system parameters that are unknown at the outset. Essentially, those are the breakdown voltage and the distance to the cable fault. In order to determine these, the following solution approach or procedure is followed.

The goal or object of the peak detection function is to find every maximum in the examined range, thus also the parasitic maxima that arise due to noise or additional inhomogeneities of the cable impedance, and to evaluate all of the detected maxima according to certain criteria. In that regard, a value that represents a reliability level or confidence value is allocated or assigned to each one of the maxima (see FIG. 4). With the aid of this additional information, then a series of test calculations is carried out in connection with a simple SPICE model for a conductor line or cable of the determined length, in which in the first step, all maxima having an assigned reliability level above a minimum confidence value are taken into consideration. If these do not correspond, or only poorly correspond, with the results of the test calculation, then further maxima are excluded, beginning with that maximum having the lowest remaining confidence value or reliability level. The results of a test calculation with this reduced set of maxima is again compared, and this sequence is repeated to find the best solution. The best solution is then displayed or otherwise indicated as an output to the user of the testing apparatus.

In order to better determine the maxima, a scale-variable filter concept is applied to the frequency spectrum. That means that the spectrum itself is regarded as a summation of harmonic functions. Thereby the basic underlying functions can be determined.

The frequency spectrum, like initially the time progression of the signal, is subjected to a further Fast Fourier Transformation (FFT). The result of this FFT is multiplied with a window function and then subsequently transformed back. With the aid of a window function (e.g. a rectangular function or a nearly rectangular function) having a certain specified window width, portions of the spectrum are filtered out. In this manner, a smoothing of the spectrum is also possible, which simplifies the determination of local maxima.

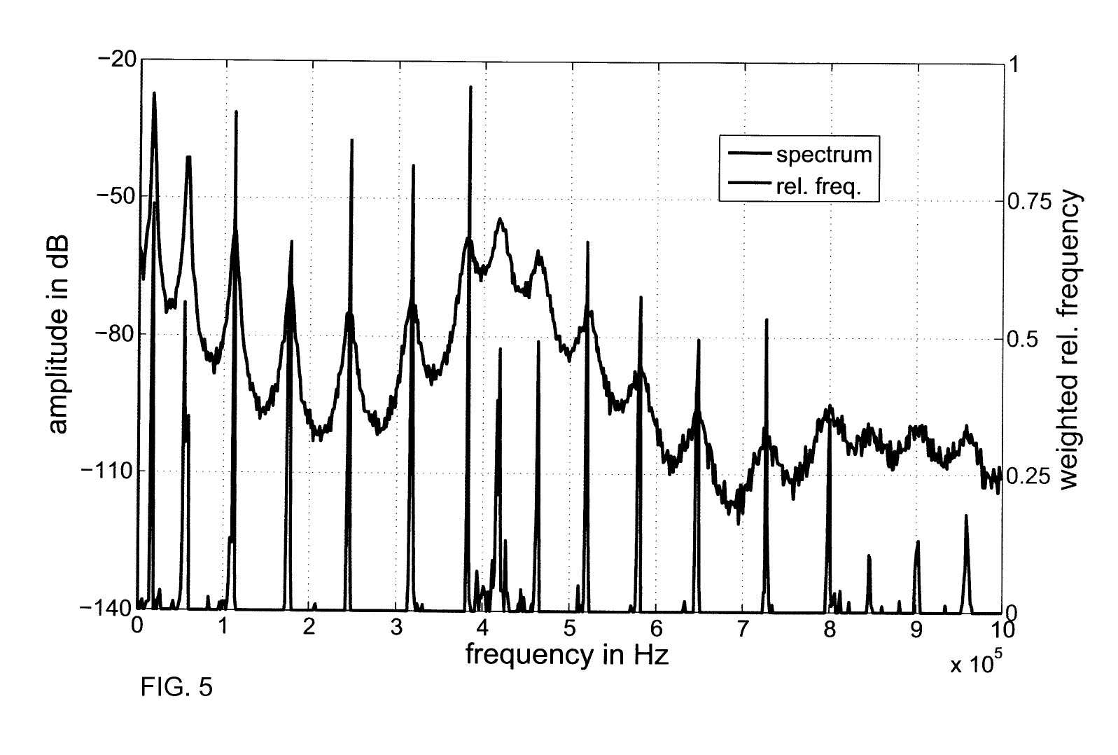

A continuously variable window function, by which harmonic signal components are added to or removed from the spectrum in a stepwise manner, predominantly realizes a scale-variable analysis of the “original spectrum”. In each one of these steps, the frequencies and the magnitude or level difference between the respective maxima and the respective neighboring minima of the reconstructed smoothed spectrum are determined and stored. Next it is then determined how often and with what significance, maxima have arisen at the respective frequencies. In this manner, a weighted frequency (of occurrence) distribution is determined, which serves as a measure or indicator of the reliability of each respective maximum (see FIG. 5).

Thus, in that manner the spectrum is “scanned” according to the harmonic components contained therein. In that regard, the start end values for the width of the window function correspond to the considered range between an assumed minimum and maximum fault location distance. The big advantage of this method is that it can be utilized on spectra with various different scale relationships without manual adaptations or adjustments of the detection being necessary.

In order to improve the detection for peaks with especially low peak levels or large peak widths, slight shifts of the maxima are taken into consideration during the step-wise filtering of the spectrum. For that, the characteristic progression is divided into intervals that will each be associated with only one maximum to a high probability. The area of the progression within the respective intervals is determined by numerical integration, and the result (i.e. the resulting integrated area) is allocated or assigned to the highest value within the interval. The result is then a data set that contains the frequencies of all determined maxima as well as the respective associated reliability values. This data set is then provided as an input to the algorithm for determining the fault location distance.

With regard to the above, the determined reliability values are to be understood as a purely relative evaluation. A normalization or norming is not carried out, because any value on which to perform the normalization would be selected purely randomly or arbitrarily.

Although the invention has been described with reference to specific example embodiments, it will be appreciated that it is intended to cover all modifications and equivalents within the scope of the appended claims. It should also be understood that the present disclosure includes all possible combinations of any individual features recited in any of the appended claims. The abstract of the disclosure does not define or limit the claimed invention, but rather merely abstracts certain features disclosed in the application.

What is claimed is:

1. A method of locating a cable fault in a cable using a testing apparatus, wherein an electrical system includes the cable and the testing apparatus, and the method comprises the steps:
a) determining a first phase rotation at a first cable end of said cable, a second phase rotation at a second cable end of said cable, and a propagation constant of said cable;
b) exciting said electrical system or said cable so as to induce an electrical oscillation in said electrical system or said cable;
c) measuring said electrical oscillation, so as to determine a frequency spectrum or a time signal;
d) performing a frequency analysis of said frequency spectrum;
e) determining a total phase rotation; and
f) determining an electrical length of said cable.

2. A method of locating a cable fault in a cable using a testing apparatus connected to a coupling point on the cable, comprising the steps:
a) from said testing apparatus, applying an electrical test signal to said cable;
b) determining a first phase rotation at said coupling point, a second phase rotation at said cable fault and at least an imaginary part of a propagation constant of said cable with respect to said test signal;
c) using said test signal, exciting electrical oscillations in said cable or in an electrical system comprising said cable and said testing apparatus;
d) in said testing apparatus, measuring said electrical oscillations and determining therefrom a frequency spectrum;
e) in said testing apparatus, performing a frequency analysis of said frequency spectrum;
f) in said testing apparatus, from said frequency spectrum, determining a total phase rotation of said test signal traveling in said cable from said coupling point to said cable fault and back to said coupling point;
g) in said testing apparatus, from at least said total phase rotation and said imaginary part of said propagation constant determining an electrical length of said cable from said coupling point to said cable fault, or from at least said total phase rotation, said imaginary part of said propagation constant and said first and second phase rotations determining a geometric length of said cable from said coupling point to said cable fault; and
h) outputting from said testing apparatus an output based on said electrical length or said geometric length as an indication of a location of said cable fault along said cable.

3. The method according to claim 2, wherein said coupling point is a first cable end of said cable.

4. The method according to claim 2, wherein said determining of said first phase rotation comprises a first specifying of said first phase rotation based on a known impedance of said testing apparatus connected to said coupling point, said determining of said second phase rotation comprises a second specifying of said second phase rotation as a 180° voltage phase rotation based on a perfect reflection at said cable fault being a short circuit, and said first and second specifying respectively comprise receiving values for said first and second phase rotations as user inputs into said testing apparatus.

5. The method according to claim 2, wherein said determining of said propagation constant comprises receiving as a user input into said testing apparatus a value for at least an imaginary part of a nominal propagation constant known for said cable.

6. The method according to claim 2, wherein said step g) comprises determining said geometric length of said cable according to
$$l = \frac{ϕ - arg ( {r}_{2} ) - arg ( {r}_{1} )}{2 β}$$
wherein l is said geometric length, φ is said total phase rotation, arg(r1) is said first phase rotation, arg(r2) is said second phase rotation, and β is said imaginary part of said propagation constant.

7. The method according to claim 2, wherein said measuring of said electrical oscillations is carried out in a time domain to produce a time domain result, and said determining of said frequency spectrum comprises transforming said time domain result into a frequency domain.

8. The method according to claim 2, wherein said measuring of said electrical oscillations and said determining of said frequency spectrum are carried out in a frequency domain.

9. The method according to claim 2, wherein said frequency analysis comprises an automatic detection of relevant maxima of said frequency spectrum.

10. The method according to claim 9, wherein said automatic detection of relevant maxima in said frequency spectrum comprises evaluating a respective local maximum with respect to at least one of a specified frequency interval width and a specified threshold value.

11. The method according to claim 9, wherein said automatic detection of relevant maxima in said frequency spectrum comprises applying a filter having a variable limit frequency to said frequency spectrum, which further comprises performing a frequency transformation of said frequency spectrum followed by multiplication with a variable window function and then return transformation to produce a filtered frequency spectrum, and wherein said relevant maxima are then determined in said filtered frequency spectrum.

12. The method according to claim 11, wherein said applying of said filter causes a shifting of one or more of said relevant maxima.

13. The method according to claim 9, wherein said detection of said relevant maxima comprises detecting said relevant maxima directly in said frequency spectrum.

14. The method according to claim 9, wherein said frequency analysis further comprises determining orders of said relevant maxima.

15. The method according to claim 9, wherein said frequency analysis further comprises allocating reliability values respectively to said relevant maxima.

16. The method according to claim 15, further comprising, in said testing apparatus, performing electronic or computer modeling of an electrical oscillation behavior of said cable or of said electrical system, for plural different reliability levels.

17. The method according to claim 16, further comprising, in said testing apparatus, selecting or excluding one or more of said relevant maxima based on said reliability values respectively allocated thereto, dependent on results of said modeling at said different reliability levels.

18. The method according to claim 16, wherein said electrical oscillation behavior in said modeling comprises a modeled breakdown voltage and a modeled electrical length of said cable.

19. A testing apparatus for performing the method according to claim 2, comprising:
a voltage source adapted to apply said electrical test signal to said cable and to excite said electrical oscillations;
means for determining said first and second phase rotations and said imaginary part of said propagation constant;
means for measuring said electrical oscillations and for determining said frequency spectrum;
means for performing said frequency analysis;
means for determining said total phase rotation;
means for determining said electrical length or said geometric length; and
an output device adapted to output said output indicating said location of said cable fault.
